(19) United States
(12) Patent Application Publication
(10) Pub. No.: US 2009/0072919 A1
(43) Pub. Date: Mar. 19, 2009

(54) VOLTAGE-CONTROLLED OSCILLATOR WITH WIDE OSCILLATION FREQUENCY RANGE AND LINEAR CHARACTERISTICS

(75) Inventors: Hui Dong Lee, Daejeon (KR); Kwi Dong Kim, Daejeon (KR); Chong Ki Kwon, Daejeon (KR); Jong Dae Kim, Daejeon (KR)

Correspondence Address: AMPACC LAW GROUP, 13024 Beverly Park Road, Suite 205, Mukilteo, WA, 98275, US

(73) Assignee: Electronics and Telecommunications Research Institute, Daejeon (KR)

(21) Appl. No.: 12/195,185

(22) Filed: Aug. 20, 2008

(30) Foreign Application Priority Data
Sep. 19, 2007 (KR) 2007-95432

(51) Int. Cl. H03B 5/12

(52) U.S. Cl. 331/117 FE

(57) ABSTRACT

Provided is a voltage-controlled oscillator with a wide oscillation frequency range and linear characteristics, which can linearly change an oscillation frequency versus control voltage due to a variable capacitance range increased by several MOS transistors additionally connected to an LC resonant circuit, and can control the oscillation frequency range by adjusting numbers, widths, lengths and operation regions of the MOS transistors. Thus, the voltage-controlled oscillator with a wide oscillation frequency range and linear control voltage-oscillation frequency characteristics without using a switching device can be implemented.

### CROSS-REFERENCE TO RELATED APPLICATION

This application claims priority to and the benefit of Korean Patent Application No. 2007-95432, filed Sep. 19, 2007, the disclosure of which is incorporated herein by reference in its entirety.

### BACKGROUND

1. Field of the Invention

The present invention relates to a voltage-controlled oscillator with a wide oscillation frequency range and linear characteristics, and more particularly, to a voltage-controlled oscillator with a wide oscillation frequency range and linear characteristics in which the range of variable capacitance expands due to several MOS transistors additionally connected to an LC resonant circuit.

The present invention is derived from a project entitled “Component Modules for Ubiquitous Terminal [2006-S-006-02]” conducted as an IT R&D program for the Ministry of Information and Communication (Republic of Korea) and the Institute for Information and Technology Advancement (Republic of Korea)

2. Discussion of Related Art

Generally, a voltage-controlled oscillator is an oscillator controlling a frequency by changing the capacitance of a variable capacitor using voltage control. Such a voltage-controlled oscillator is an essential part of all types of electrical communication systems, and may be used to up- or down-convert a frequency with respect to a predetermined signal.

FIG. 1A is a circuit diagram of a conventional LC voltage-controlled oscillator, FIG. 1B is a view illustrating a method of changing an oscillation frequency range according to a variable inductance in the conventional LC voltage-controlled oscillator, and FIG. 1C is a view illustrating a method of changing an oscillation frequency range according to a variable capacitance in the conventional LC voltage-controlled oscillator.

As illustrated in FIG. 1A, a conventional LC voltage-controlled oscillator 100 includes an LC resonant circuit 130 oscillating a frequency according to a control voltage VC, and an amplification circuit 150 amplifying an oscillation frequency output from the LC resonant circuit 130. Their connection will be briefly described below.

First, first and second variable inductors L1 and L2 are connected between a power supply VDD, and first and second nodes Q11 and Q12, a first variable varactor CV1 is connected between a control voltage terminal VC and the first node Q11, and a second variable varactor CV2 is connected between the control voltage terminal VC and the second node Q12. Drain, gate and source terminals of a first NMOS transistor NM1 are connected to the first node Q11, the second node Q12 and a third node Q13, respectively, and drain, gate and source terminals of a second NMOS transistor NM2 are connected to the second, first and third nodes Q12, Q11 and Q13, respectively. A current source Is is connected between the third node Q13 and a ground GND.

In the LC voltage-controlled oscillator 100, when L denotes the total variable inductance of first and second variable inductors L1 and L2, and C denotes the total variable capacitance of first and second variable varactors CV1 and CV2, and thus the oscillation frequency (f_{osc}) may be expressed as Formula 1.

$${f}_{osc} = \frac{1}{2 π \sqrt{L \cdot C}} \qquad [ Formula 1 ]$$

As seen from Formula 1, an oscillation frequency range may be dependant on the total variable inductance (L) and the total variable capacitance (C) of the LC resonant circuit 130.

To implement a voltage-controlled oscillator having a wide oscillation frequency range using this principle, as illustrated in FIG. 1B, several switches are connected to a predetermined part of a spiral electrode to change a turn number according to the turn-on/off of the switch, thereby varying the total inductance, which is disclosed in Korean Patent Publication No. 2004-0078533 (publication date: Sep. 10, 2004).

However, the variable inductor formed in the above configuration has variable inductance values which are discretely changed, so that it is not appropriate to linearly change the oscillation frequency range.

Alternatively, to change the oscillation frequency range, as illustrated in FIG. 1C, a method of changing the total capacitance by a variable capacitor part Z including two variable varactors Ca and Cb in which capacitances are dependant on a control voltage VC, and a capacitor-array in which the capacitance of each stage is dependant on the turn-on/off of a switch, is disclosed in Korean Patent Publication No. 2004-0085629 (publication date: Oct. 08, 2004).

However, the variable capacitor part Z has to include a control voltage adjusting device and a switch in or out of a chip for switching the capacitor-array. Thus, it has a complicated configuration, and signal distortion occurs during switching.

### SUMMARY OF THE INVENTION

The present invention is directed to implementation of a voltage-controlled oscillator which has a simple structure, a wide oscillation frequency range and linear control voltage-oscillation frequency characteristics.

One aspect of the present invention provides a voltage-controlled oscillator with a wide oscillation frequency range and linear characteristics, including: an LC resonant circuit oscillating a frequency according to a control voltage; and an amplification circuit amplifying the oscillation frequency, wherein the LC resonant circuit comprises: an inductor; a first variable capacitance part including first and second variable varactors connected in parallel to the inductor, and having a first variable capacitance value according to a first control voltage; and a second variable capacitance part including first and second transistors connected in parallel to the first and second variable varactors, respectively, and having a second variable capacitance value according to a second control voltage.

Another aspect of the present invention provides a voltage-controlled oscillator with a wide oscillation frequency range and linear characteristics, including: an LC resonant circuit oscillating an oscillation frequency according to a control voltage; and an amplification circuit amplifying the oscillation frequency, wherein the LC resonant circuit comprises: an inductor; a first variable capacitance part including first and second variable varactors connected in parallel to the inductor, and having a first variable capacitance value according to a first control voltage; and a second variable capacitance part including first to 2N-th transistors having pairs configured in a multi stage and connected in parallel to the first and second variable varactors, and having a second variable capacitance value according to a second control voltage.

Here, in the transistors included in the second variable capacitance part, source and drain terminals may be short-circuited with one another, and gate terminals may be commonly connected to the second control voltage. According to a second variable capacitance value of the transistors included in the second variable capacitance part, the oscillation frequency according to a control voltage may be linearly changed, and the oscillation frequency may be changed according to width, length and operation region of the transistor.

### BRIEF DESCRIPTION OF THE DRAWINGS

The above and other objects, features and advantages of the present invention will become more apparent to those of ordinary skill in the art by describing in detail preferred embodiments thereof with reference to the attached drawings in which:

FIG. 1A is a circuit diagram of a conventional LC voltage-controlled oscillator;

FIG. 1B is a view illustrating a method for changing an oscillation frequency range according to a variable inductance in the conventional LC voltage-controlled oscillator;

FIG. 1C is a view illustrating a method for changing an oscillation frequency range according to a variable capacitance in the conventional LC voltage-controlled oscillator;

FIG. 2 is a circuit diagram of a voltage-controlled oscillator according to a first exemplary embodiment of the present invention;

FIG. 3A is a graph illustrating the change of capacitance according to a control voltage of a variable varactor, and FIG. 3B shows a graph of an oscillation frequency according to a control voltage when an LC resonant circuit has a variable varactor with the same characteristics as those in FIG. 3A;

FIG. 4 is a graph illustrating the change of capacitance according to a control voltage of a PMOS transistor;

FIG. 5A shows a computer simulation result of the total capacitance versus control voltage in the LC resonant circuit of FIG. 2, and FIG. 5B shows a graph of oscillation frequency versus control voltage when the total capacitance of the LC resonant circuit is the same as in FIG. 5A, in which all data are obtained from the simulation;

FIG. 6 is a circuit diagram of a voltage-controlled oscillator according to a second exemplary embodiment of the present invention; and

FIG. 7 is a circuit diagram of a voltage-controlled oscillator according to a third exemplary embodiment of the present invention.

### DETAILED DESCRIPTION OF PREFERRED EMBODIMENTS

Hereinafter, a voltage-controlled oscillator having a wide oscillation frequency range and linear characteristics will be described with reference to accompanying drawings in detail.

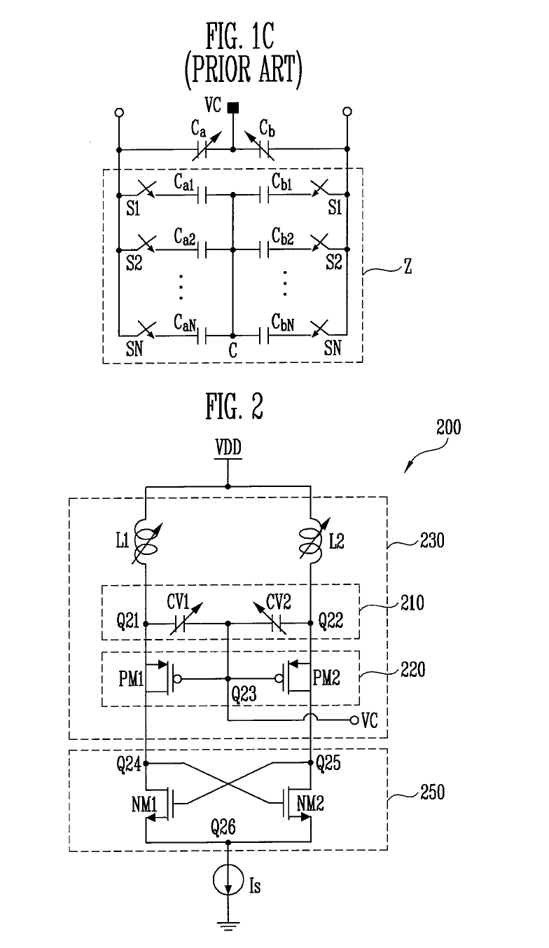

FIG. 2 is a circuit diagram of a voltage-controlled oscillator according to a first exemplary embodiment of the present invention.

Referring to FIG. 2, a voltage-controlled oscillator 200 includes an LC resonant circuit 230 oscillating a frequency according to a control voltage VC, and an amplification circuit 250 amplifying an oscillation frequency output from the LC resonant circuit 230.

The LC resonant circuit 230 includes first and second variable inductors L1 and L2, a first variable capacitance part 210 having first and second variable varactors CV1 and CV2 connected in parallel to the first and second variable inductors L1 and L2, respectively, and a second variable capacitance part 220 having first and second PMOS transistors PM1 and PM2 connected in parallel to the first and second variable varactors CV1 and CV2, respectively. The LC resonant circuit 230 may be coupled to various types of amplification circuits.

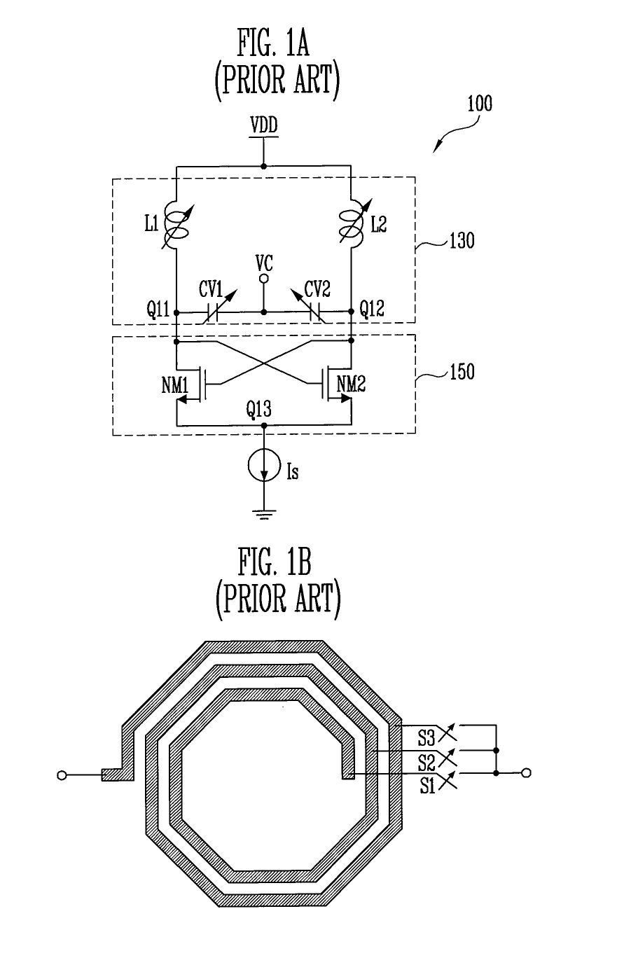

That is, the voltage-controlled oscillator 200 according to the present invention has the same components as that of FIG. 1A, except that the LC resonant circuit 230 further includes the second variable capacitance part 220 having the first and second PMOS transistors PM1 and PM2 besides the first variable capacitance part 210 having the first and second variable varactors CV1 and CV2.

First, the connections between the respective components will be described in more detail.

First and second inductors L1 and L2 are connected between a power supply VDD, and first and second nodes Q21 and Q22, respectively, a first variable varactor CV1 is connected between a control voltage terminal VC and the first node Q21, and a second variable varactor CV2 is connected between the control voltage terminal VC and the second node Q22. Source, gate and drain terminals of a first PMOS transistor PM1 is connected to the first node Q21, a third node Q23 and a fourth node Q24, respectively, and source, gate and drain terminals of a second PMOS transistor PM2 are connected to the second node Q22, the third node Q23 and a fifth node Q25, respectively.

Here, in the first and second PMOS transistors PM1 and PM2, the source and drain terminals may be short-circuited with one another, and the gate terminals may be commonly connected to the control voltage terminal VC.

Drain, gate and source terminals of a first NMOS transistor NM1 are connected to the fourth node Q24, the fifth node Q25 and a sixth node Q26, respectively, and drain, gate and source terminals of a second NMOS transistor NM2 are connected to the fifth, forth and sixth nodes Q25, Q24 and Q26, respectively.

In the present embodiment, while the LC resonant circuit 230 includes the first and second variable inductors L1 and L2 having a variable inductance value, it may include only one variable inductor, or a fixed inductor.

Meanwhile, the present invention is characterized in that an oscillation frequency range is changed by changing variable capacitance using the first and second variable varactors CV1 and CV2 and the first and second PMOS transistors PM1 and PM2 without a switching device, so a method for changing variable capacitance by a transistor according to the present invention will be described in more detail below.

In the voltage-controlled oscillator formed as in FIG. 2, if the first and second variable inductors L1 and L2 have a fixed inductance value, components affecting an oscillation frequency may be the first and second various varactors CV1 and CV2 and the first and second PMOS transistors PM1 and PM2.

First, the effect of the first and second variable varactors CV1 and CV2 on the oscillation frequency is as follows.

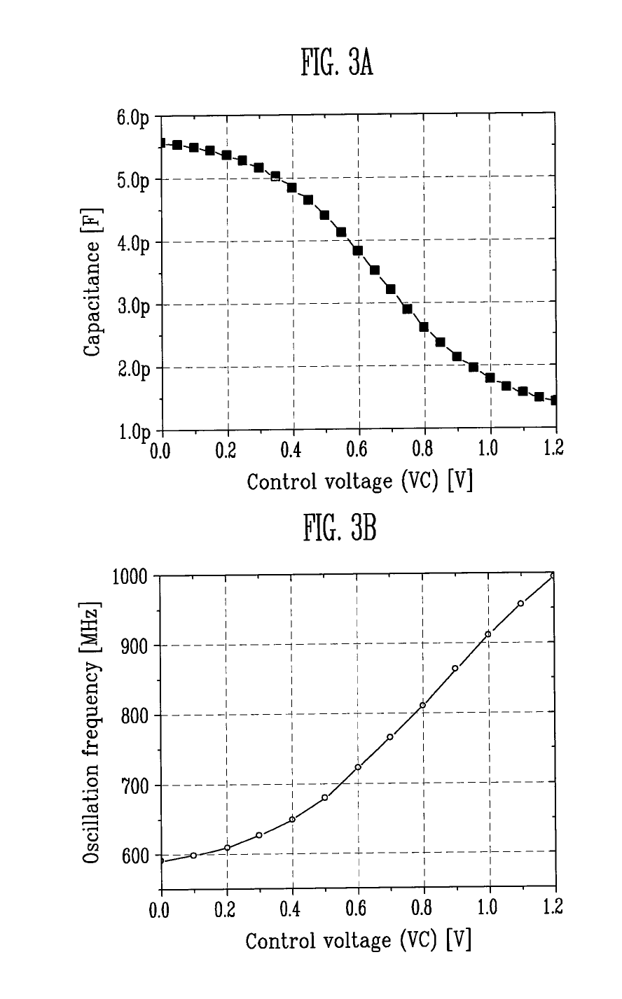

FIG. 3A is a graph illustrating the change of capacitance according to a control voltage of the first and second varactors CV1 and CV2, and FIG. 3B is a graph illustrating the change of an oscillation frequency according to a control voltage when an LC resonant circuit includes the first and second variable varactors CV1 and CV2, which have the same characteristic as those in FIG. 3A.

As illustrated in FIG. 3A, the first and second variable varactors CV1 and CV2 have non-linearity in a control voltage VC section ranging from 0 to 0.4V, and thus, as illustrated in FIG. 3B, the oscillation frequency also changes non-linearly in the corresponding section.

Then, the effect of the first and second PMOS transistors PM1 and PM2 on the oscillation frequency is as follows.

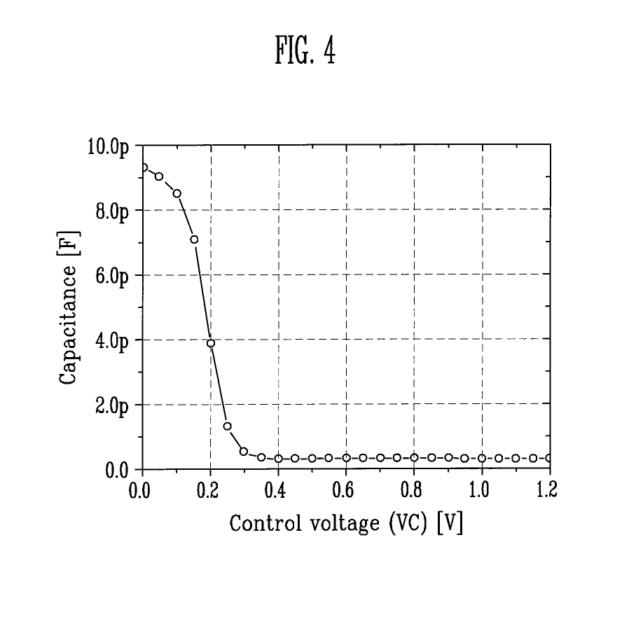

FIG. 4 is a graph illustrating the change of capacitance according to a control voltage of the first and second PMOS transistors PM1 and PM2. As illustrated in FIG. 4, it can be seen that the capacitance values of the first and second PMOS transistors PM1 and PM2 drastically change in the control voltage VC section ranging from 0 to 0.4V.

Accordingly, the present invention taking advantage of such characteristics of the first and second variable varactors CV1 and CV2 and the first and second PMOS transistors PM1 and PM2 may additionally connect the first and second PMOS transistors PM1 and PM2 to the LC resonant circuit 230, as illustrated in FIG. 2, to highly increase a capacitance value in a predetermined control voltage section (e.g., 0 to 0.4V), thereby linearly changing an oscillation frequency.

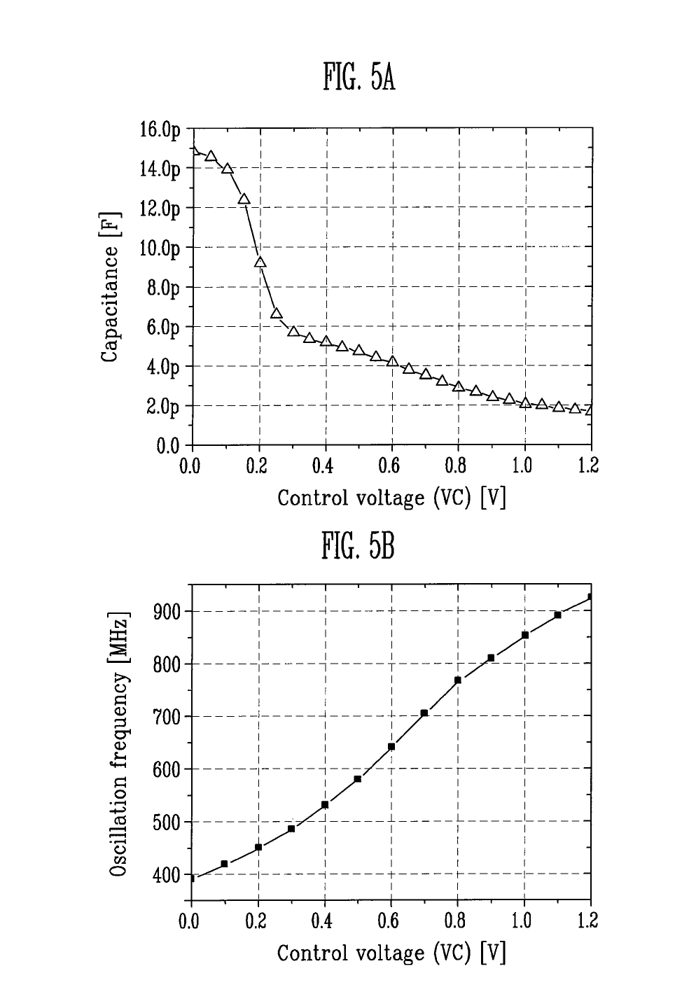

FIG. 5A shows a computer simulation result of the total capacitance versus control voltage in the LC resonant circuit of FIG. 2, and FIG. 5B shows a graph of oscillation frequency versus control voltage when the total capacitance of the LC resonant circuit is the same as in FIG. 5A, in which all data are obtained from the simulation. Here, the results shown in FIGS. 5A and 5B include parasitic components of a circuit, and thus there is a less difference from the results even if effects of the parasitic components are eliminated.

As illustrated in FIG. 5A, the total capacitance in the voltage-controlled oscillator 200 formed as FIG. 2 highly increases in a control voltage section ranging from 0 to 0.4V, compared to the graphs of FIGS. 3A and 4, and thus the relationship between a control voltage and an oscillation frequency is linear, as illustrated in FIG. 5B. Further, a variation range of the oscillation frequency ranges from 400 to 920 MHz, which is 1.3 times wider than that in FIG. 4B (e.g., 590 to 990 MHz).

Accordingly, the voltage-controlled oscillator 200 according to the present invention may expand the oscillation frequency range by increasing the range of variable capacitance due to the first and second PMOS transistors PM1 and PM2 additionally connected to the LC resonant circuit 230 without a switching device, and may linearly change an oscillation frequency according to a control voltage. Further, the voltage-controlled oscillator 200 may be applied to other oscillator circuits because of its simpler structure than the conventional voltage-controlled oscillator using the switching device, and the easy control of the oscillation frequency range by adjusting the widths, lengths and operation regions of the first and second PMOS transistors PM1 and PM2.

### Exemplary Embodiment 2

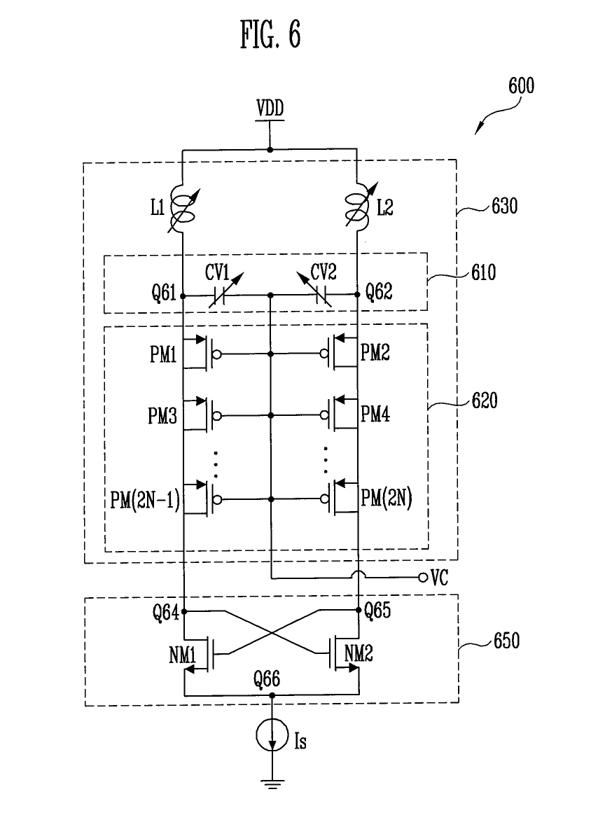

FIG. 6 is a circuit diagram of a voltage-controlled oscillator according to a second exemplary embodiment of the present invention.

Referring to FIG. 6, the voltage-controlled oscillation 600 includes the same component as that of FIG. 2 except that several pairs of PMOS transistors PM1, PM2, . . . , and PM(2N) are connected in a multi stage to a second variable capacitance part 620, each pair being in parallel to one another.

That is, in the second variable capacitance part 620, several pairs of PMOS transistors PM1, PM2, . . . , and PM(2N) are in parallel to one another, each of which has source and drain terminals short-circuited with each other, and a gate terminal to which a control voltage VC is applied.

Here, the sizes and operation regions of the PMOS transistors PM1, PM2, . . . , and PM(2M) may vary by each stage, and the polarities of the gates, sources and drains of the PMOS transistors PM1, PM2, . . . , and PM(2N) may be converted, and NMOS transistors may be used instead of the PMOS transistors.

The first and second variable inductors L1 and L2 may be inductors having a fixed inductance value, or inductors having a variable inductance value by multiple switching. The first and second variable varactors CV1 and CV2 may be formed of several varactor diodes changing continuously, or varactor diodes capable of discretely changing a capacitance value by multiple switching.

In the voltage-controlled oscillator 600 having such a configuration, each of the PMOS transistors PM1, PM2, . . . , and PM(2N) included in the second variable capacitance part 620 has a wider variable capacitance range than that of the first and second variable varactors CV1 and CV2 by adding all capacitance values which drastically increase in a specific control voltage section (e.g., 0V-0.4V).

Accordingly, the voltage-controlled oscillator 600 has a wider oscillation frequency range than that of FIG. 2, since the variable capacitance range becomes wider due to the several PMOS transistors PM1, PM2, . . . , and PM(2N) included in the second variable capacitance part 620. Further, the oscillation frequency according to the control voltage may be linearly changed by increasing variable capacitance due to the several PMOS transistors PM1, PM2, . . . , and PM(2N), and the range of the oscillation frequency may be simply controlled by adjusting the width, length and operation region of each PMOS transistor PM1, PM2, . . . or PM(2N). For these reasons, the present oscillator may be easily applied to other oscillator circuits.

### Exemplary Embodiment 3

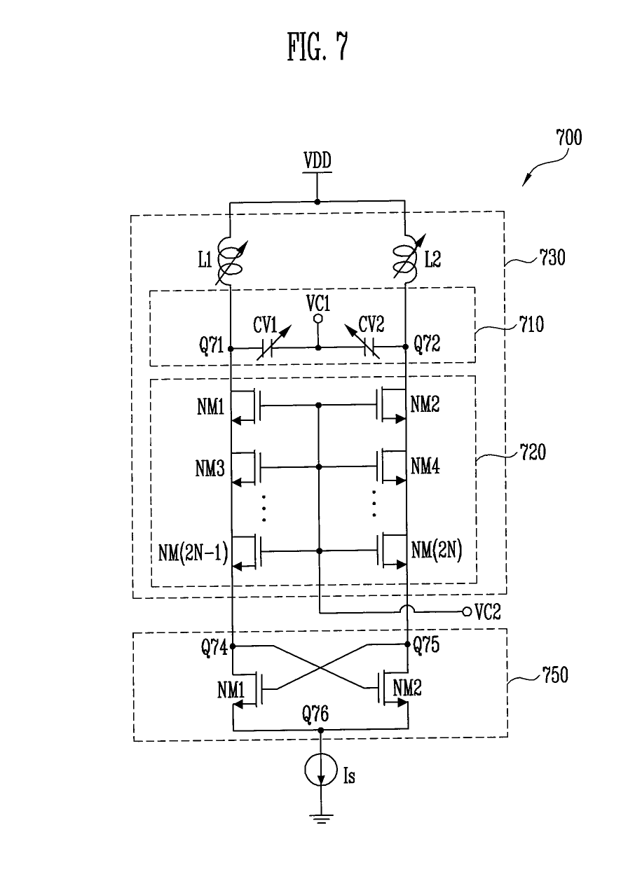

FIG. 7 is a circuit diagram of a voltage-controlled oscillator 700 according to a third exemplary embodiment of the present invention.

Referring to FIG. 7, the voltage-controlled oscillator 700 has the same configuration as that of FIG. 6, except that a first control voltage VC1 is applied to first and second variable varactors CV1 and CV2 of a first variable capacitance part 710, a second variable capacitance part 720 includes several pairs of NMOS transistors NM1, NM2, . . . , and NM(2N) configured in a multi stage and connected in parallel to the first and second variable varactors CV1 and CV2, and a second control voltage VC2 is applied to gate terminals of the NMOS transistors NM1, NM2, . . . , and NM(2N).

In the second variable capacitance part 720, the range of oscillation frequency may be increased due to different control voltages applied to each stage.

Accordingly, the voltage-controlled oscillator 700 may expand the range of oscillation frequency by increasing the range of variable capacitance due to several NMOS transistors NM1, NM2, . . . , and NM(2N) included in the second variable capacitance part 720 without a switching device, and linearly change the oscillation frequency according to a control voltage. Further, the voltage-controlled oscillator 700 has a wider oscillation frequency range than that of FIG. 6 due to several different control voltages. Furthermore, the oscillation frequency range may be varied by adjusting the width, length and operation region of each NMOS transistor NM1, NM2, . . . or NM(2N), and thus the present oscillator may be easily applied to other oscillator circuits.

According to the present invention, since a variable capacitance range may be increased due to several MOS transistors additionally connected to an LC resonant circuit, an oscillation frequency range may be increased and an oscillation frequency according to a control voltage may be linearly changed, and thus a voltage-controlled oscillator having a wide oscillation frequency range and linear control voltage-oscillation frequency characteristics without using a switching device may be implemented.

Further, compared to a conventional voltage-controlled oscillator using a switching device, the present voltage-controlled oscillator may have a simpler configuration, and thus enhance the integration density of a circuit.

Furthermore, since the oscillation frequency range may be simply controlled by adjusting the width, length and operation region of each MOS transistor additionally connected to the LC resonant circuit, the present oscillator may be easily applied to other oscillator circuits.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A voltage-controlled oscillator with a wide oscillation frequency range and linear characteristics, comprising:
an LC resonant circuit oscillating a frequency according to a control voltage; and
an amplification circuit amplifying the oscillation frequency,
wherein the LC resonant circuit comprises:
an inductor;
a first variable capacitance part including first and second variable varactors connected in parallel to the inductor, and having a first variable capacitance value according to a first control voltage; and
a second variable capacitance part including first and second transistors connected in parallel to the first and second variable varactors, respectively, and having a second variable capacitance value according to a second control voltage.

2. The voltage-controlled oscillator according to claim 1, wherein source terminals are short-circuited with drain terminals and gate terminals are commonly connected to the second control voltage in the first and second transistors.

3. The voltage-controlled oscillator according to claim 1, wherein the oscillation frequency to the control voltage is linearly changed according to the second variable capacitance values of the first and second transistors.

4. The voltage-controlled oscillator according to claim 1, wherein the oscillation frequency depends on the widths, lengths and operation regions of the first and second transistors.

5. The voltage-controlled oscillator according to claim 1, wherein the first and second transistors are NMOS or PMOS transistors.

6. The voltage-controlled oscillator according to claim 1, wherein the first and second control voltages are different from or equal to each other.

7. The voltage-controlled oscillator according to claim 1, wherein the inductor is a fixed inductor or a variable inductor.

8. The voltage-controlled oscillator according to claim 1, wherein the LC resonant circuit includes at least one inductor.

9. The voltage-controlled oscillator according to claim 1, the first variable capacitance part includes at least two variable varactors.

10. A voltage-controlled oscillator with a wide oscillation frequency range and linear characteristics, comprising:
an LC resonant circuit oscillating an oscillation frequency according to a control voltage; and
an amplification circuit amplifying the oscillation frequency,
wherein the LC resonant circuit comprises:
an inductor;
a first variable capacitance part including first and second variable varactors connected in parallel to the inductor, and having a first variable capacitance value according to a first control voltage; and
a second variable capacitance part including first to 2N-th transistors having pairs configured in a multi stage and connected in parallel to the first and second variable varactors, and having a second variable capacitance value according to a second control voltage.

11. The voltage-controlled oscillator according to claim 10, wherein
source terminals are short-circuited with drain terminals and gate terminals are commonly connected to the second control voltage in the first to 2N-th transistors.

12. The voltage-controlled oscillator according to claim 10, wherein
the oscillation frequency to the control voltage is linearly changed according to the second variable capacitance values of the first to 2N-th transistors.

13. The voltage-controlled oscillator according to claim 10, wherein the oscillation frequency depends on the widths, lengths and operation regions of the first to 2N-th transistors.

14. The voltage-controlled oscillator according to claim 10, wherein the first to 2N-th transistors are NMOS or PMOS transistors.

15. The voltage-controlled oscillator according to claim 10, wherein the first and second control voltages are different from or equal to each other.

16. The voltage-controlled oscillator according to claim 10, wherein when the second control voltage includes 2-1st to 2-N-th control voltages different from each other, the 2-1st to 2-N-th voltages are applied to the transistors of each stage, which has pairs configured in a multi stage, respectively.
